(19) United States
(12) Patent Application Publication
(10) Pub. No.: US 2009/0159966 A1
(43) Pub. Date: Jun. 25, 2009

(54) High voltage semiconductor device, method of fabricating the same, and method of fabricating the same and a low voltage semiconductor device together on a substrate

(76) Inventor: Chih-Jen Huang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/960,723

(22) Filed: Dec. 20, 2007

(51) Int. Cl. H01L 27/088; H01L 21/8234

(52) U.S. Cl. 257/334; 438/270; 257/E21.616; 257/E27.06

(57) ABSTRACT

A high voltage semiconductor device comprises a substrate, a well, a gate structure, and a source/drain structure in a grade region in a well in the substrate. The gate structure is disposed on the substrate with a portion vertically down into a trench in the well in the substrate and has a relatively small size. The method of fabricating the high voltage semiconductor device comprises forming a first trench for an STI structure and a second trench for a gate structure, depositing an oxide layer on the substrate to fill the first and the second trenches, wherein a void is formed in the second trench, performing a photolithography and etching process to remove a portion of the oxide layer in the second trench, and forming a gate on the gate dielectric layer in the second trench.

### BACKGROUND OF THE INVENTION

1. Field of the Invention

The present invention relates to semiconductor technology, and particularly to a high voltage (HV) semiconductor device, a method of fabricating the same, and a method of fabricating the same and a low voltage (LV) semiconductor device together on a substrate, in which the HV device is a plane device having a vertical channel.

2. Description of the Prior Art

Many applications for semiconductor devices require power devices, for example, laterally diffused metal-oxide-semiconductor (LDMOS) devices, vertical double-diffusion MOS (VDMOS) devices, and double diffused drain MOS (DDDMOS) devices.

For example, a liquid crystal display (LCD) driver IC can operate at high voltage to drive the LCD and at low voltage to drive an associated logic circuit. A double diffused drain MOS (DDDMOS) transistor is a typical power device to sustain the higher operating voltage. FIG. 1 illustrates a transistor 1 including a substrate 10 having a well region 12 formed therein and field oxide regions 1 4 formed thereon, a gate structure 16, a pair of doping regions 18 and a pair of source/drain regions 20. The gate structure 16 comprising a gate dielectric layer 22, an overlying gate 24, and a spacer 26 on the sidewall of the gate 24 is disposed overlying the well region 12 of the substrate 10 and bounded by the field oxide regions 14. The pair of source/drain regions 20 is formed within the pair of doping regions 18. The gate length, L₁, of such type of conventional transistor may be typically about 2 micrometers (μm).

Generally, size minimization of a semiconductor device is desired. However, such type of HV device has a limited size and is difficult to be further minimized due to the gate length. Therefore, there is still a need for a novel HV semiconductor device having a relatively small size.

### SUMMARY OF THE INVENTION

One object of the present invention is to provide an HV semiconductor device, which is a plane device with a vertical channel and thus has a relatively small size as compared with a conventional one. Accordingly the device pitch can be minimized.

Another object of the present invention is to provide a method of fabricating the HV semiconductor device of the present invention, in which a high aspect ratio of the trench for the gate structure is utilized to facilitate the formation of the trench.

Still another object of the present invention is to provide a method of fabricating the HV semiconductor device of the present invention and an LV semiconductor device together on a substrate, in which the fabrication of the HV semiconductor device and the fabrication of the LV semiconductor device are well compatible without extra process loading.

From one aspect of the present invention, the HV semiconductor device according to the present invention comprises a substrate, a well, a gate structure, and a source/drain structure. The well is first-conductivity-type-doped and formed in the substrate. The gate structure is disposed on the substrate with a portion vertically down into a trench in the well in the substrate. The source/drain structure is second-conductivity-type-doped and formed in two second-conductivity-type-doped grade regions in the well in the substrate on two sides of the gate structure.

From another aspect of the present invention, the method of fabricating an HV semiconductor device comprises the steps as follows. A substrate is provided. A well is formed in the substrate. A mask layer is formed on the substrate and patterned such that the mask layer has openings to expose a shallow trench isolation (STI) region and a gate region. A portion of the substrate through each of the openings is removed to form a first trench for an STI structure and a second trench for a gate structure. An oxide layer is deposited on the substrate to fill the first and the second trenches, wherein a void is formed in the second trench. A photolithography and etching process is performed to remove a portion of the oxide layer in the second trench. A planarization process is performed to planarize the oxide layer using the mask layer as a stop layer. The mask layer is removed. An HV gate dielectric layer is conformally formed on the substrate. A second ion implantation is performed to form two grade regions on two sides of the gate region. A gate is formed on the gate dielectric layer in the second trench. A spacer is formed on each of the two sides of the gate. A third ion implantation is performed to form a source structure and a drain structure in the two grade regions on the two sides of the gate.

From still another aspect of the present invention, the method of fabricating an HV semiconductor device and an LV semiconductor device together on a substrate comprises steps as follows. A substrate having an HV region and an LV region is provided. A first trench for the first STI structure in the HV region and a second trench for the first gate structure in the HV region and a third trench for the second STI structure in the LV region are simultaneously formed through a patterned mask layer formed on the substrate. An oxide layer is deposited on the substrate to fill the first, second, and third trenches, wherein a void is formed in the second trench. A photolithography and etching process is performed to remove a portion of the oxide layer in the second trench. A planarization process is performed to remove a portion of the oxide layer using the mask layer as a stop layer. A first ion implantation is performed to form a well in each of the HV region and the LV region of the substrate. An HV gate dielectric layer is conformally formed on the substrate. A portion of the HV gate dielectric layer on the LV region is removed. An LV gate dielectric layer is formed on the LV region. A layer of gate material is formed on the substrate, wherein the second trench is filled with the gate material. The layer of gate material is patterned to simultaneously form the first gate in the HV region and the second gate in the LV region. A grade region is formed in the substrate on each of two sides of the first gate. A spacer is formed on each of a sidewall of the first gate and a sidewall of the second gate. A third ion implantation is performed to form a source/drain structure in the grade region in the substrate on each of two sides of the first gate and two sides of the second gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view illustrating a transistor of a conventional technology;

FIG. 2 is a cross-sectional view illustrating a transistor as an embodiment of the HV semiconductor device according to the present invention;

FIGS. 3 through 8 are cross-sectional views showing the process steps in an embodiment of the method of fabricating an HV semiconductor device according to the present invention;

FIGS. 9 through 13 are cross-sectional views showing an embodiment of the method of fabricating an HV semiconductor device and an LV semiconductor device together on a substrate according to the present invention; and

FIGS. 14 through 17 are cross-sectional views showing another embodiment of the method of fabricating an HV semiconductor device and an LV semiconductor device together on a substrate according to the present invention.

### DETAILED DESCRIPTION

The present invention particularly relates to an HV semiconductor device, a method of fabricating the same, and a method of fabricating the same and an LV semiconductor device together on a substrate. The present disclosure may repeat reference numerals and/or letters in the various examples. This repetition is for the purpose of simplicity and clarity and does not in itself dictate a relationship between the various embodiments and/or configurations discussed.

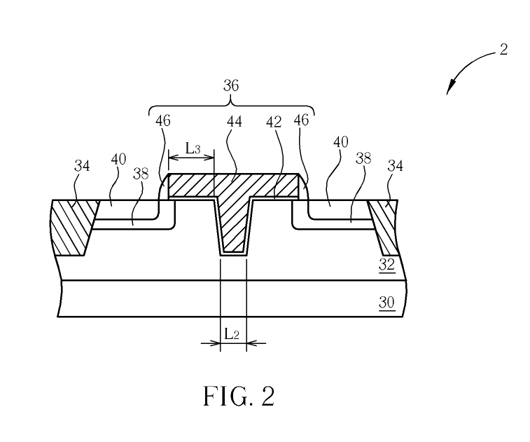

FIG. 2 illustrates a transistor as an embodiment of the HV semiconductor device according to the present invention. The transistor 2 includes a substrate 30 having a well 32 formed therein, a gate structure 36, a pair of grade regions 38 and a pair of source/drain 40. It is understood that the polarities shown in figures are exemplary, and suitable modification of the polarities can be made to form an HV PMOS or NMOS transistor device. Thus, the substrate 30 may be, such as an N or P-type silicon substrate or other semiconductor substrate. The gate structure 36 is disposed overlying the well 32 of the substrate 30 and may comprise a gate dielectric layer 42 and a gate 44, and may further comprise a spacer 46 on a sidewall of the gate 44. The gate dielectric layer 42 and the gate 44 are disposed partially in a trench in the substrate 30 and partially above the trench. Furthermore, the gate structure 36 may have a portion over the trench to overlie the substrate beside the trench, such that the gate structure 36 and the diffusion region (including source/drain, or grade region) overlap. The gate 44 may comprise polysilicon or other electric conductive material. The gate dielectric layer 42 may comprise for example silicon dioxide. The spacer 46 may comprise dielectric material. The pair of source/drain 40 is formed within the pair of grade regions 38. The well 32 may be implanted with an N-type dopant, and the grade regions 38 and the source/drain 40 may be implanted with a P-type dopant. Alternatively, the well 32 may be implanted with a P-type dopant, and the grade regions 38 and the source/drain 40 may be implanted with an N-type dopant. The gate structure 36 and the source/drain 40 may be further bounded by an STI structure 34.

The gate length of the device as shown in FIG. 2 substantially equals to the sum of the heights of the two walls, the width, L₂, of the bottom of the trench, and the widths, L₃, of the two gate/diffusion overlap regions. In one embodiment, the gate length is about 2 μm as conventionally applied in conventional transistor devices, the width, L₂, may be about 0.15 μm when the height of the wall is 0.4 μm, and L₃ may be 0.525 μm. Accordingly, the size of the gate, in this case, shrinks from 2 μm to 1.2 μm and becomes 60% of the conventional size. In the present invention, the trench width, L₂, may be at least two fold of the thickness of the HV gate dielectric layer and the size of the gate structure is small and may be in the range of one sixth to one eighth of the conventional gate size, L₁. The aspect ratio of the trench for the gate (finally processed) may be 2.0 to 5.0, and preferably 2.5 to 3.5. In another embodiment, the HV gate dielectric layer has a thickness of about 500 angstroms (Å) and the trench for the gate structure has a height of about 0.4 μm and a width of about 0.15 μm.

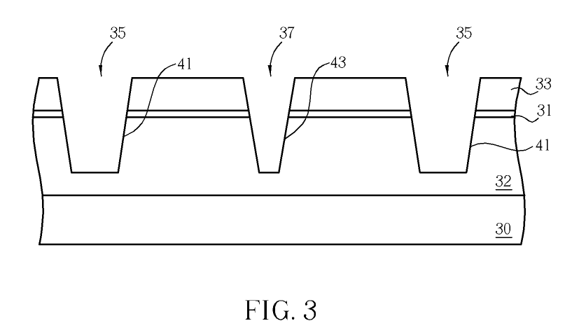

FIGS. 3 through 8 are cross-sectional views showing the process steps in an embodiment of the method of fabricating an HV semiconductor device in accordance with one aspect of the present invention. First, in FIG. 3, a substrate 30 is provided. A well 32 is formed in the substrate 30 by conventional ion implantation. For example, an N-well can be formed by phosphorus ion implantation with a dosage of about 1×10¹² to 1×10¹⁴ ions/cm². A P-well can be formed by boron ion implantation with a dosage of about 2×10¹² to 2×10¹⁴ ions/cm². Thereafter, a pad oxide 31 is optionally formed on the substrate 30 by thermal oxidation. A nitride layer 33 may be formed on the pad oxide 31 and patterned by a conventional photolithography and etching process to serving as a mask, such that the mask has openings 35 and 37 to expose an STI region and a gate region. Thereafter, the exposed portion of the substrate 30 is removed by, for example, etching, as conventional technology for making STI, through each of the openings 35 and 37, to form trenches 41 and 43 for an STI structure and a gate respectively. The width of the trench 43 is greater than two fold of the thickness of the HV gate dielectric layer 42 and can be about one tenth to one sixteenth of a conventional gate length of the conventional HV device under a same gate length. Furthermore, the resulting space in the trench after the formation of the gate dielectric layer needs to be enough for filling the gate material therein. In one embodiment, the width of the trench 43 may be 0.15 μm, the height of the trench 43 may be 0.4 μm, and the thickness of the nitride layer 33 may be 0.16 μm. Accordingly, the aspect ratio of the trench 43 is calculated by (0.4+0.16)/0.15 equaling to about 4. The width of the trench 41 is 0.4 μm. The trench for the STI is always wider than the trench for the gate.

Thereafter, a liner 39 may be further formed on the bottoms and the sidewalls of the trenches. For example, the liner may be a thermally grown oxide layer.

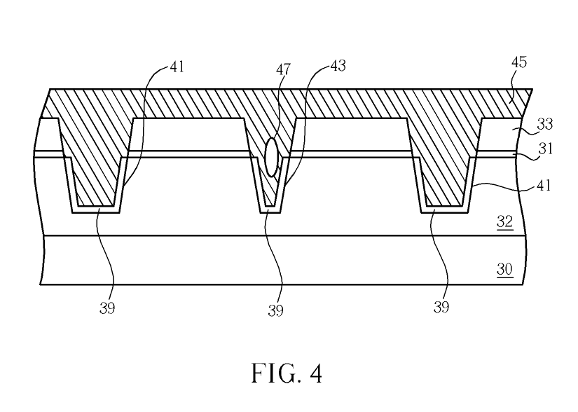

Thereafter, in FIG. 4, an oxide layer 45 is deposited on the substrate to fill the trenches 41 and 43, by, for example, high-density plasma chemical vapor deposition. It should be noted that since the trench 43 has a high aspect ratio, a void 47 is formed in the trench 43, while the trench 41 for the STI structure is normally formed without voids.

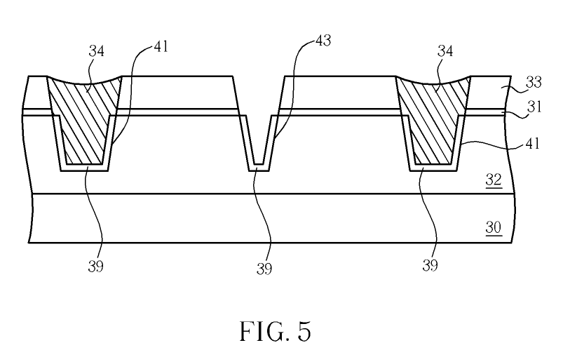

Thereafter, please refer to FIG. 5, a photolithography and etching process is performed to remove a portion of the oxide layer 45 in the trench 43. The removal is easy due to the existing void. The etching process may be for example dry or wet etching or both. Thereafter, a planarization process, for example, chemical-mechanical polishing (CMP) process, is performed to planarize the oxide layer 45 using the nitride layer 33 as a stop layer. Thus, an STI structure 34 is obtained. Thereafter, the nitride layer 33 is removed by, for example, wet etching.

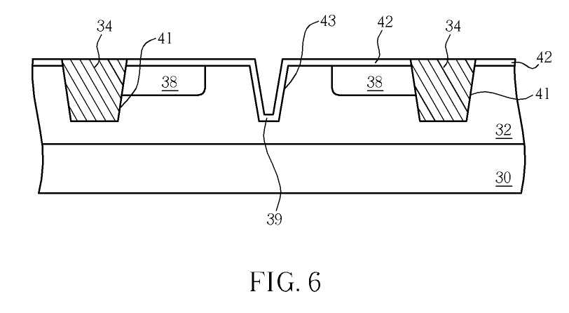

Please refer to FIG. 6. An HV gate dielectric layer 42 is conformally formed on the substrate 30 by, for example, thermal oxidation. Thereafter, one grade region 38 is formed by ion implantation in the well 32 in the substrate 30 on each of two sides of the gate region using a patterned photoresist layer as a mask (not shown). The dosage of the implantation may be 10¹²-10¹⁴ atoms/cm².

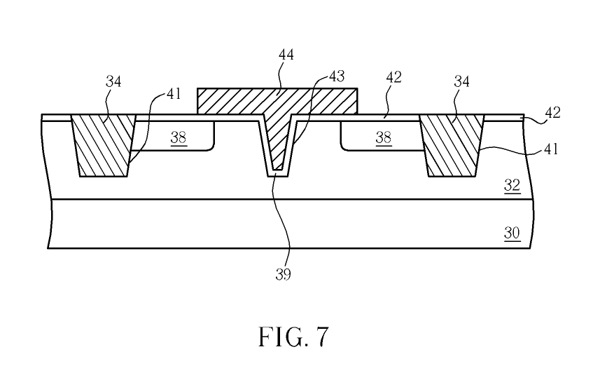

Thereafter, a polysilicon layer is deposited on the substrate 30 to fill the trench 43. The polysilicon layer is patterned by a photolithography and an etching process to form a gate 44 in and over the trench 43, as shown in FIG. 7.

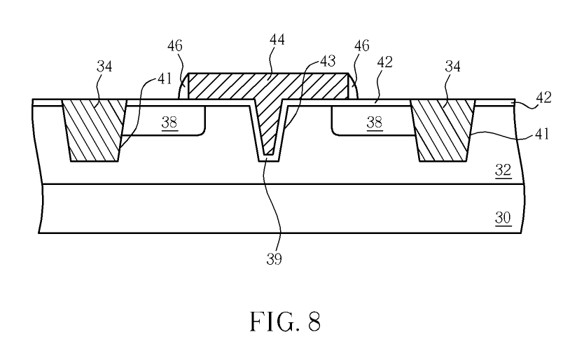

Thereafter, referring to FIG. 8, a spacer 46 is formed on each of the two sides of the gate 44. A source and a drain 40 are formed by ion implantation in the two grade regions 38 on the two sides of the gate 44 using the gate 44 and the spacer 46 as a mask. The portion of the gate dielectric layer 42 not under the gate 44 may be removed or just remains on the substrate.

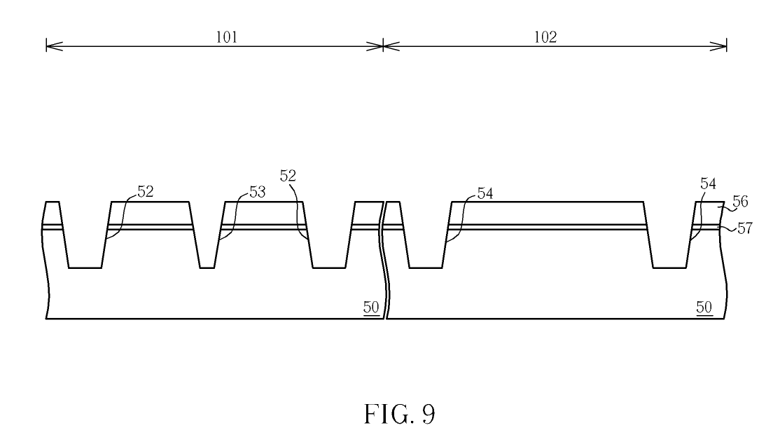

The HV semiconductor device of the present invention can be easily fabricated compatibly with the fabrication of a conventional LV semiconductor device, without extra process loading. FIGS. 9 through 13 illustrate an embodiment of the method of fabricating an HV semiconductor device and an LV semiconductor device together on a substrate.

Please refer to FIG. 9. First, a substrate 50 is provided. The substrate 50 has a high voltage region (HV region) 101 and a low voltage region (LV region) 102. Trenches 52, 53 in HV region 101 and trench 54 in LV region 102 are simultaneously formed by etching through a patterned mask layer formed on the substrate 50. The patterned mask layer may be a nitride layer 56 formed on a pad oxide 57 on the substrate 50. The trench 53 has a width and an aspect ratio as mentioned above for the trench 43. A liner (not shown) may be formed on the bottoms and the sidewalls of the trenches.

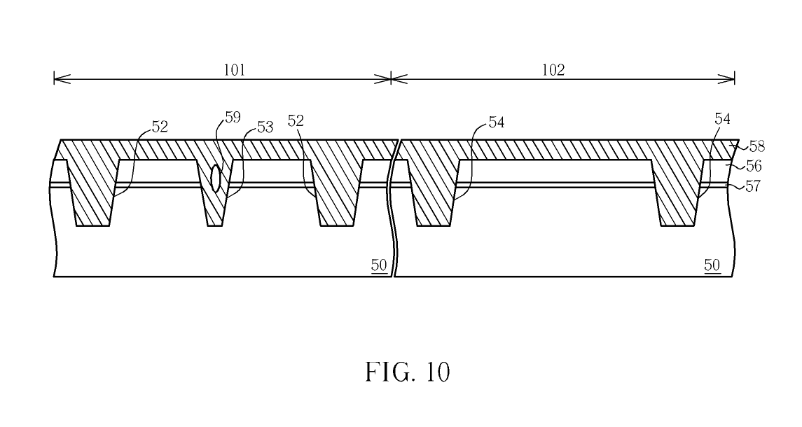

Thereafter, referring to FIG. 10, an oxide layer 58 is deposited on the substrate to fill the trenches 52, 53, and 54. A void 59 is formed in the trench 53 due to the aspect ratio and the width of the trench 53.

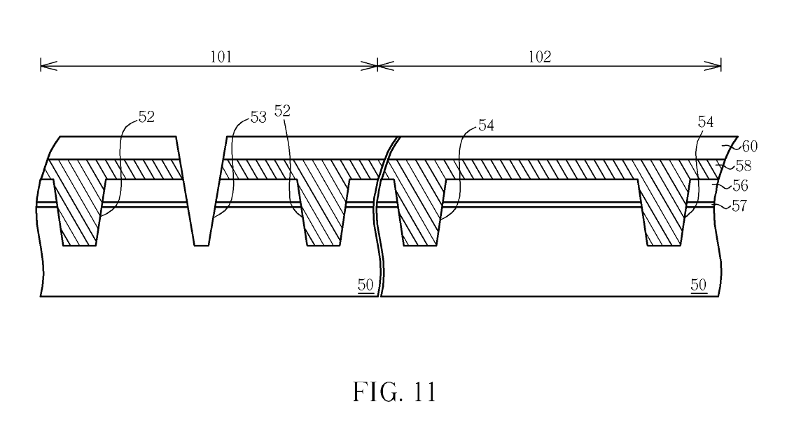

Referring to FIG. 11, a photolithography and etching process is performed to remove the portion of the oxide layer 58 in the trench 53 through a patterned photoresist layer 60 formed on the substrate 50. Thereafter, the photoresist layer 60 is removed. A planarization process is performed to remove a portion of the oxide layer 58 using the nitride layer 56 as a stop layer. Thereafter, the nitride layer 56 is removed. The pad oxide 57 may be removed optionally.

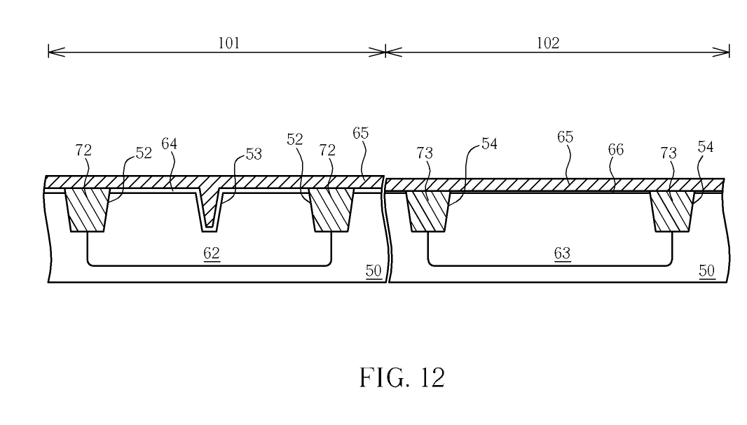

Referring to FIG. 12, STI structures 72 and 73 are formed after the oxide layer 58 is planarized. Thereafter, a well 62 and a well 63 are simultaneously formed in the HV region 101 and the LV region 102 of the substrate respectively by ion implantation. Thereafter, an HV gate dielectric layer 64 is conformally formed on the substrate 50, such that the HV gate dielectric layer 64 is formed on the HV region 101 and the LV region 102, as well as the sidewalls and the bottom of the trench 53. The HV gate dielectric layer 64 may be a gate oxide layer with a conventional thickness, for example, 350 Å. Thereafter, the portion of the HV gate dielectric layer 64 formed on the LV region 102 is removed by, for example, etching. An LV gate dielectric layer 66 is then formed on the LV region 102 of the substrate 50. The LV gate dielectric layer 66 may be conformally formed on the entire substrate and may have a conventional thickness, for example, 65 Å. A layer of gate material 65 is deposited on the HV and LV gate dielectric layer on the substrate 50, and the trench 53 is filled with the gate material. The gate material may comprise polysilicon and the like.

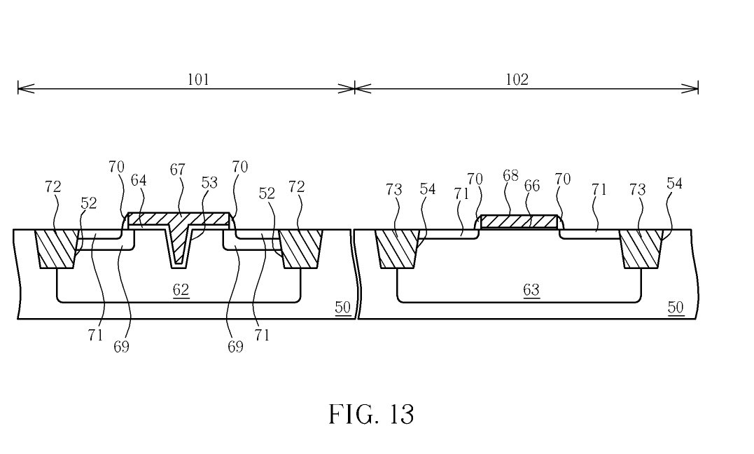

Referring to FIG. 13, the layer of gate material 65 is patterned to simultaneously form the first gate 67 in the HV region 101 and the second gate 68 in the LV region 102. The first gate 67 is thus located vertically down into the well 62 in the substrate 50. A grade region 69 is formed in the substrate 50 on each of two sides of the first gate 67 by ion implantation. Thereafter, a spacer 70 is formed on the sidewall of the first gate 67 and the sidewall of the second gate 68. The pair of source/drain 71 are formed in the substrate 50 on two sides of the first gate 67 and two sides of the second gate 68 by ion implantation. Finally, an HV semiconductor device and an LV semiconductor device are formed together on a substrate.

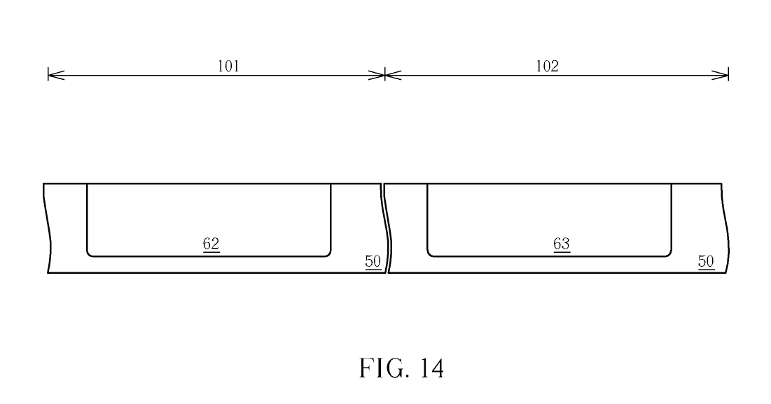

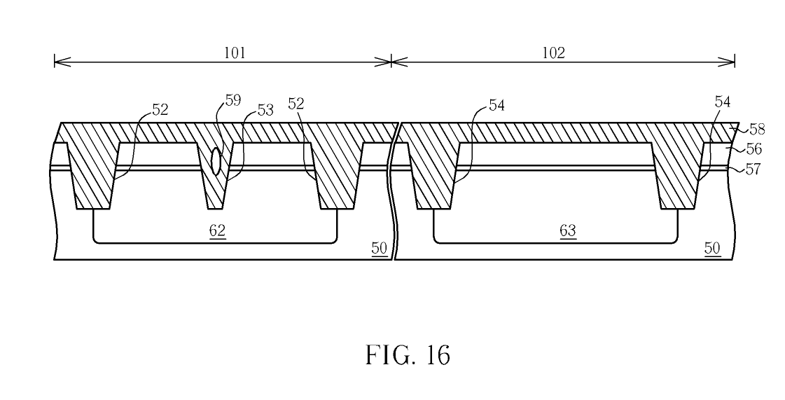

FIGS. 14 through 17 illustrate another embodiment of the method of fabricating an HV semiconductor device and an LV semiconductor device together on a substrate. Please refer to FIG. 14. First, a substrate 50 is provided. The substrate 50 has an HV region 101 and an LV region 102. It is different from the embodiment described above that, in this embodiment, a well 62 are formed in the HV region 101, and a well 63 are formed in the LV region 102 of the substrate by ion implantation, before the trenches are formed.

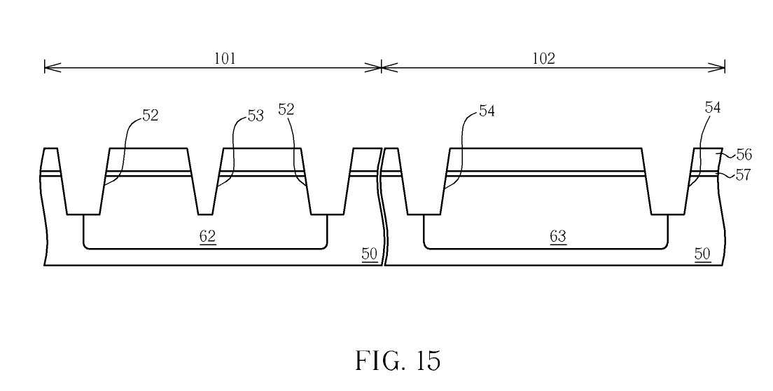

Thereafter, referring to FIG. 15, trenches 52, 53 and trench 54 are simultaneously formed in the HV region 101 and the LV region 102 by etching through a patterned mask layer formed on the substrate 50 respectively. The patterned mask layer may be a nitride layer 56 formed on a pad oxide 57 on the substrate 50. The trench 53 has a width as mentioned above for the trench 43. A liner may be formed on the bottoms and the sidewalls of the trenches (not shown).

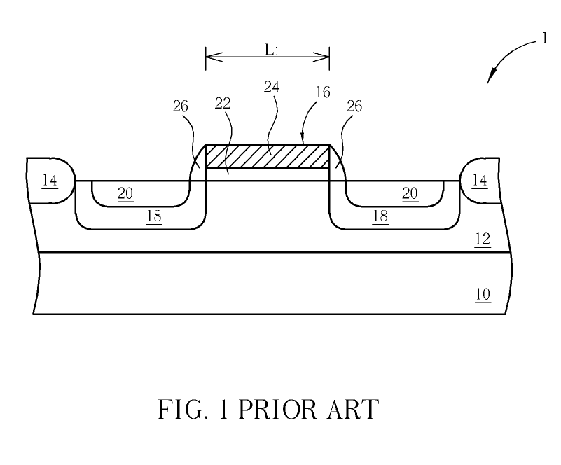

Thereafter, referring to FIG. 1 6, an oxide layer 58 is deposited on the substrate to fill the trenches 52, 53, and 54. A void 59 is formed in the trench 53 due to the aspect ratio and the width of the trench 53.

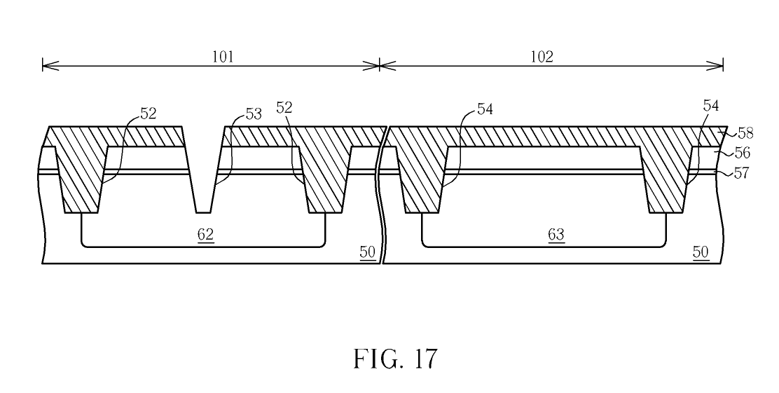

Referring to FIG. 17, a photolithography and etching process is performed to remove the portion of the oxide layer 58 in the trench 53 through a patterned photoresist layer (not shown) formed on the substrate 50. After the oxide layer in the trench 53 is removed, the photoresist layer is removed. Then, a planarization process is performed to remove the portion of the oxide layer 58 on the nitride layer 56 using the nitride layer 56 as a stop layer. Thereafter, the nitride layer 56 is removed. The pad oxide 57 may be removed optionally.

Thereafter, an HV gate dielectric layer 64 is conformally formed on the substrate 50, such that the trench 53 has a gate dielectric layer formed on the sidewalls and the bottom. Thereafter, the portion of the HV gate dielectric layer 64 formed on the LV region 102 is removed by, for example, etching. An LV gate dielectric layer 66 is then formed on the LV region 102 of the substrate 50. A layer of gate material 65 is deposited on the substrate 50, and the trench 53 is filled with the gate material. After the layer of gate material 65 is deposited, the cross-sectional view of the substrate is presented substantially as same as FIG. 12. Thereafter, the subsequent steps of the fabrication are the same as those described above referring to FIG. 13.

Without departing from the scope or the spirit of the present invention, the method of the present invention also may be conveniently apply to the fabrication of an HV CMOS device and an LV CMOS device together on a substrate. In the process, trenches for STI structures and HV gates, gate structures, same type doped regions can be simultaneously formed, respectively.

All combinations and sub-combinations of the above-described features also belong to the present invention. Those skilled in the art will readily observe that numerous modifications and alterations of the device and method may be made while retaining the teachings of the invention.

What is claimed is:

1. A high voltage semiconductor device, comprising:
a substrate;
a well of a first conductivity type formed in the substrate;
a gate structure disposed on the substrate and with a portion vertically down into the well in the substrate; and
a source structure and a drain structure of a second conductivity type respectively formed in two grade regions of the second conductivity type in the well in the substrate on two sides of the gate structure.

2. The device of claim 1, wherein the gate structure comprises:
a gate, and
a gate dielectric layer disposed between the gate and the substrate.

3. The device of claim 1, wherein the gate structure comprises: a gate,
a spacer disposed on a sidewall of the gate above the substrate, and
a gate dielectric layer disposed between the gate and the substrate.

4. The device of claim 1, wherein the gate structure has a portion overlapping the source structure and the drain structure.

5. The device of claim 1, wherein the first conductivity type is one of N-type and P-type, and the second conductivity type is the other of N-type and P-type.

6. The device of claim 1, wherein the portion of the gate structure vertically down into the well in the substrate has an aspect ratio in a range of 2.0 to 5.0.

7. A method of fabricating a high voltage semiconductor device, comprising:
providing a substrate;
performing a first ion implantation to form a well in the substrate;
forming a mask layer on the substrate and patterning the mask layer such that the mask layer have openings to expose a shallow trench isolation region and a gate region;
removing a portion of the substrate through each of the openings to form a first trench for a shallow trench isolation structure and a second trench for a gate structure;
depositing an oxide layer on the substrate to fill the first and second trenches, wherein a void is formed in the second trench;
performing a photolithography and etching process to remove a portion of the oxide layer in the second trench;
performing a planarization process to planarize the oxide layer using the mask layer as a stop layer;
removing the mask layer;
conformally forming a high voltage gate dielectric layer on the substrate;
performing a second ion implantation to form two grade regions on two sides of the gate region;
forming a gate on the gate dielectric layer in the second trench;
forming a spacer on each of the two sides of the gate; and
performing a third ion implantation to form a source structure and a drain structure in the two grade regions on the two sides of the gate structure.

8. The method of claim 7, wherein the second trench has an aspect ratio in a range of 2.0 to 5.0.

9. The method of claim 7, wherein the well is P-type doped, the grade regions are N-type doped, and the source structure and the drain structure are N-type doped.

10. The method of claim 7, wherein the well is N-type doped, the grade regions are P-type doped, and the source structure and the drain structure are P-type doped.

11. The method of claim 7, wherein the step of depositing an oxide layer on the substrate to fill the first trench and the second trench is performed by a high-density plasma chemical vapor deposition process.

12. The method of claim 7, wherein the step of removing the mask layer is performed by a wet etching process.

13. A method of fabricating a high voltage semiconductor device and a low voltage semiconductor device together on a substrate, comprising:
providing a substrate having a high voltage region and a low voltage region;
simultaneously forming a first trench for a first shallow trench isolation structure in the high voltage region, a second trench for a first gate structure in the high voltage region, and a third trench for a second shallow trench isolation structure in the low voltage region, through a patterned mask layer formed on the substrate;
depositing an oxide layer on the substrate to fill the first, second, and third trenches, wherein a void is formed in the second trench;
performing a photolithography and etching process to remove a portion of the oxide layer in the second trench;
performing a planarization process to remove a portion of the oxide layer using the mask layer as a stop layer;
performing a first ion implantation to form a well in each of the high voltage region and the low voltage region of the substrate;
conformally forming a high voltage gate dielectric layer on the substrate;
removing a portion of the high voltage gate dielectric layer on the low voltage region;
forming a low voltage gate dielectric layer on the low voltage region;
depositing a layer of gate material on the substrate, wherein the second trench is filled with the gate material;
patterning the layer of gate material to simultaneously form a first gate in the high voltage region and a second gate in the low voltage region;
performing a second ion implantation to form a grade region in the substrate on each of two sides of the first gate;
forming a spacer on each of a sidewall of the first gate and a sidewall of the second gate; and
performing a third ion implantation process to form a source/drain structure in the grade region in the substrate on each of two sides of the first gate and two sides of the second gate.

14. The method of claim 13, wherein the step of performing a first ion implantation to form a well in each of the high voltage region and the low voltage region of the substrate is performed before the step of simultaneously forming a first trench for the first shallow trench isolation structure in the high voltage region and a second trench for the first gate structure in the high voltage region and a third trench for the second shallow trench isolation structure in the low voltage region, through a patterned mask layer formed on the substrate.

15. The method of claim 13, wherein the step of performing a first ion implantation to form a well in each of the high voltage region and the low voltage region of the substrate is performed after the step of performing a planarization process to remove a portion of the oxide layer using the mask layer as a stop layer.

16. The method of claim 13, wherein the second trench has an aspect ratio in a range of 2.0 to 5.0.

17. The method of claim 13, wherein the gate dielectric layer comprises silicon dioxide.

18. The method of claim 13, wherein the step of depositing an oxide layer on the substrate to fill the first, second, and third trenches is performed by a high-density plasma chemical vapor deposition process.

19. The method of claim 13, wherein the step of removing the mask layer is performed by a wet etching process.

20. The method of claim 13, wherein the high voltage gate dielectric layer is thicker than the low voltage gate dielectric layer.
